(19) United States
(12) Patent Application Publication
(10) Pub. No.: US 2005/0026084 A1
(43) Pub. Date: Feb. 3, 2005

(54) Semiconductor device and method for elimination of resist linewidth slimming by fluorination

(76) Inventors: Cesar M. Garza, Round Rock, TX (US); Willard E. Conley, Austin, TX (US); William J. Taylor JR., Round Rock, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/631,283

(22) Filed: Jul. 31, 2003

(51) Int. Cl. G03F 7/00

(52) U.S. Cl. 430/311; 430/327

(57) ABSTRACT

A semiconductor device (10) includes a photoresist layer (20) for patterning features on the semiconductor device (10) during manufacturing. After the photoresist layer (20) is deposited, the semiconductor device (10) is exposed to fluorine using a fluorination module (126). In one embodiment, the fluorine is applied via a plasma in the fluorination module (126). In other embodiments, the fluorine may be applied in other gaseous or liquid forms. Fluorinating the photoresist layer (20) functions to prevent slimming of the features when dimensions of the features are measured using a scanning electron microscope (SEM).

### FIELD OF THE INVENTION

The present disclosure, generally, relates to semiconductor devices and a method of making the same, and more particularly, to a semiconductor device and method for elimination of resist linewidth slimming by fluorination.

### RELATED ART

In recent developments, 193 nm lithography has been identified as a key technology enabler for 130 nm and 90 nm nodes. However, 193 nm photoresists suffer from a phenomenon referred to as linewidth slimming. The phenomenon consists of a reduction of the resist printed image when inspected or measured in an SEM (scanning electron microscope). The maximum shrinkage is on the order of approximately 15% (fifteen percent) of the original image size, but it varies as a function of resist formulation and electron beam landing energy and flux. This slimming transfers after the etch and clean up steps, producing local undesirable physical changes which in turn, affects an intended functionality of the semiconductor device being manufactured.

Accordingly, it would be desirable to provide a method for elimination of resist linewidth slimming that overcomes these and other problems in the art.

### SUMMARY

According to one embodiment of the present disclosure, a method for forming a semiconductor device includes providing a substrate; forming a predetermined layer on the substrate; forming a photoresist layer on the predetermined layer; and exposing the photoresist layer to fluorine to produce a fluorinated photoresist layer.

### BRIEF DESCRIPTION OF THE DRAWINGS

The embodiments of the present disclosure are illustrated by way of example and not limited by the accompanying figures, in which like references indicate similar elements, and in which:

FIG. 1 is a layout view of a portion of a semiconductor device having a patterned feature of photoresist affected by linewidth slimming;

FIG. 2 is a cross-section view of the semiconductor device of FIG. 1 taken along line 2-2;

FIG. 3 is a cross-section view of the semiconductor device of FIG. 1 taken along line 3-3;

FIG. 4 is a layout view of a portion of a semiconductor device having a patterned feature of photoresist with substantially no linewidth slimming according to one embodiment of the present disclosure;

FIG. 5 is a cross-section view of the semiconductor device of FIG. 4 taken along line 5-5;

FIG. 6 is a flow diagram of a method for patterning a portion of a semiconductor device with substantial elimination of resist linewidth slimming according to one embodiment of the present disclosure;

FIG. 7 is a flow diagram of the wafer patterning process in the flow diagram of FIG. 6 presented in greater detail according to one embodiment of the present disclosure;

FIG. 8 is a graphical representation illustrating changes in critical dimension linewidth versus a number of occurrences an SEM measurement is taken on untreated pattern lines of a dense line pattern and treated pattern lines of the same dense line pattern according to an embodiment of the present disclosure;

FIG. 9 is a graphical representation illustrating changes in critical dimension linewidth versus a number of occurrences an SEM measurement is taken on untreated pattern lines of a semi-dense line pattern and treated pattern lines of the same semi-dense line pattern according to another embodiment of the method of the present disclosure;

FIG. 10 is a graphical representation illustrating changes in critical dimension linewidth versus a number of times an SEM measurement is taken on untreated pattern lines of an isolated line pattern and treated pattern lines of the same line pattern according to another embodiment of the method of the present disclosure;

FIG. 11 is a graphical representation of suppression of resist slimming by fluorination as a function of percentage fluorine according to one embodiment of the present disclosure; and

FIG. 12 illustrates a block diagram view of a system for use in a portion of a process for making a semiconductor device according to one embodiment of the present disclosure.

Skilled artisans appreciate that elements in the figures are illustrated for simplicity and clarity and have not necessarily been drawn to scale. For example, the dimensions of some of the elements in the figures may be exaggerated relative to other elements to help improve an understanding of the embodiments of the present disclosure.

### DETAILED DESCRIPTION

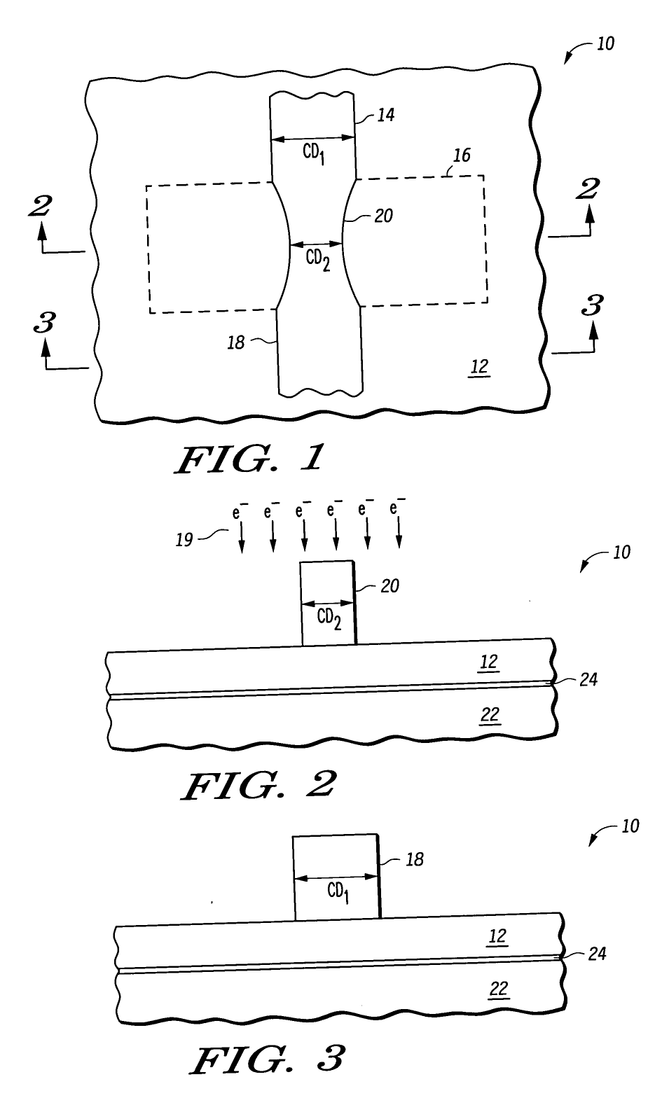

Turning now to FIG. 1, the figure shows a layout view of a semiconductor device 10 having a patterned feature of photoresist affected by linewidth slimming. In particular, semiconductor device 10 includes a polysilicon layer 12 having a photoresist pattern 14 overlying the polysilicon layer 12. During an SEM inspection step, the photoresist pattern 14 is exposed to electrons within an exposure region 16, for example, designated by a dashed line. A portion 18 of the photoresist pattern 14 lies outside the region 16, while a portion 20 lies within the region 16. The photoresist pattern 14 has a critical dimension designated by CD₁. Absent a treatment with the embodiments of the present disclosure, the portion 20 of photoresist pattern 14 is subject to suffering a reduced critical dimension, designated by CD₂, subsequent to an SEM exposure.

FIG. 2 is a cross-section view of the semiconductor device 10 of FIG. 1 taken along line 2-2. FIG. 2 illustrates electrons and electron bombardment, indicated by reference numeral 19, of the SEM exposure onto portion 20 of photoresist pattern 14. As indicated above, the portion 20 is subject to degradation, corresponding to a linewidth slimming to a line width CD₂, less than CD₁, in response to the SEM exposure. In addition, FIG. 2 illustrates a substrate 22 having an overlying dielectric 24, such as a gate dielectric. Substrate 22 may include any suitable substrate and/or multiple layers of a substrate for a particular semiconductor device.

FIG. 3 is a cross-section view of the semiconductor device 10 of FIG. 1 taken along line 3-3. FIG. 3 illustrates the portion 16, not subject to degradation from SEM exposure, since portion 16 is outside the region of the SEM exposure. Portion 16 maintains linewidth CD₁.

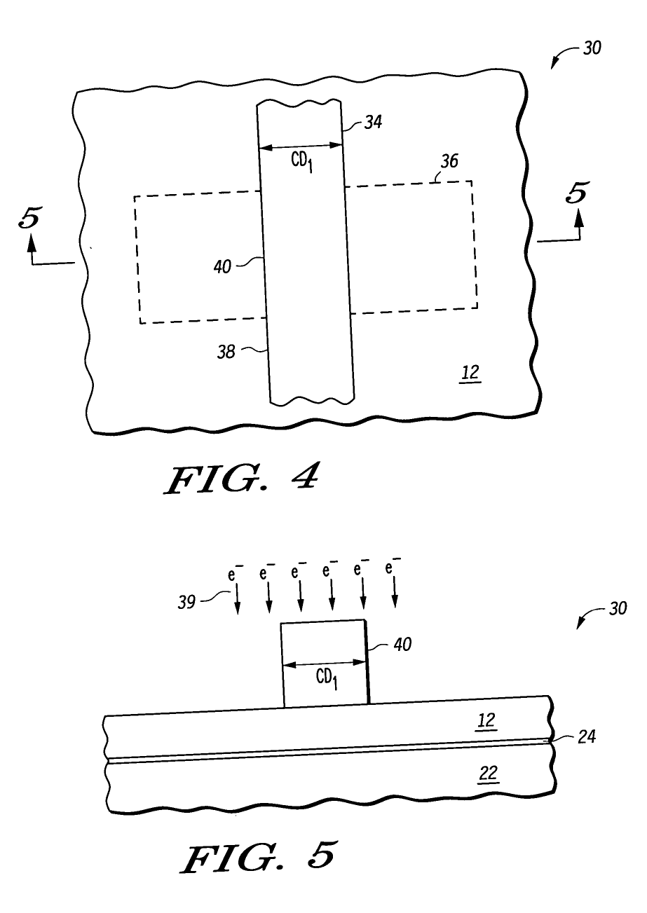

FIG. 4 is a layout view of a semiconductor device having a patterned feature of photoresist with substantially no linewidth slimming according to one embodiment of the present disclosure. In particular, semiconductor device 30 includes a polysilicon layer 12 having a photoresist pattern 34 overlying the polysilicon layer 12. During an SEM inspection step, the photoresist pattern 34 is exposed to electrons within a region, for example, designated by reference numeral 36. A portion 38 of the photoresist pattern 34 lies outside the region 36, while a portion 40 lies within the region 36. The photoresist pattern 34 has a critical dimension designated by CD₁. With a treatment according to the embodiments of the present disclosure, the portion 40 of photoresist pattern 34 is subject to substantially eliminating a reduced critical dimension subsequent to an SEM exposure.

FIG. 5 is a cross-section view of the semiconductor device of FIG. 4 taken along line 5-5. FIG. 5 illustrates electrons and electron bombardment, indicated by reference numeral 39, of the SEM exposure onto portion 40 of photoresist pattern 34. As indicated above, the portion 40 is not subject to degradation, corresponding to a substantial elimination of linewidth slimming in response to the SEM exposure. The linewidth of portion 40 is on the order of dimension CD₁. In addition, FIG. 5 illustrates a substrate 22 having an overlying dielectric 24, such as a gate dielectric. Substrate 22 may include any suitable substrate and/or multiple layers of a substrate for a particular semiconductor device.

In accordance with one embodiment of the present disclosure, the patterned photoresist is fluorinated as discussed herein. Fluorination involves replacing H atoms with F atoms. This can be accomplished from the gas phase using F₂ gas or a F plasma, and from the liquid phase using a fluorination agent. Moreover, in one embodiment, resist slimming can be substantially eliminated by fluorinating the resist after the relief image has been formed by exposing the printed resist pattern to fluorine gas or to a fluorine plasma. Conditions are selected such that the pattern integrity is maintained after fluorination. In another embodiment, resist slimming can also be substantially eliminated by fluorinating from the liquid phase. Accordingly, defects associated with the phenomenon of resist slimming are substantially eliminated, thereby improving in-line metrology in the process of manufacturing a semiconductor device.

According to one embodiment of the present disclosure, a method for forming a semiconductor device includes providing a substrate, forming a predetermined layer on the substrate; forming a photoresist layer on the predetermined layer; and exposing the photoresist layer to fluorine to produce a fluorinated photoresist layer. For example, the predetermined layer can include one of a conductive material, a semiconductive material or an insulating material.

In another embodiment, the photoresist layer is a patterned photoresist layer. In addition, the method includes using a scanning electron microscope (SEM) to measure a dimension of a portion of the patterned photoresist layer, wherein the dimension is substantially unchanged by an electron beam emitted by the SEM. The method further includes etching the portion of the patterned photoresist layer to change the dimension to a smaller dimension. In yet another embodiment, the portion of the patterned photoresist layer is for forming a control electrode of a transistor.

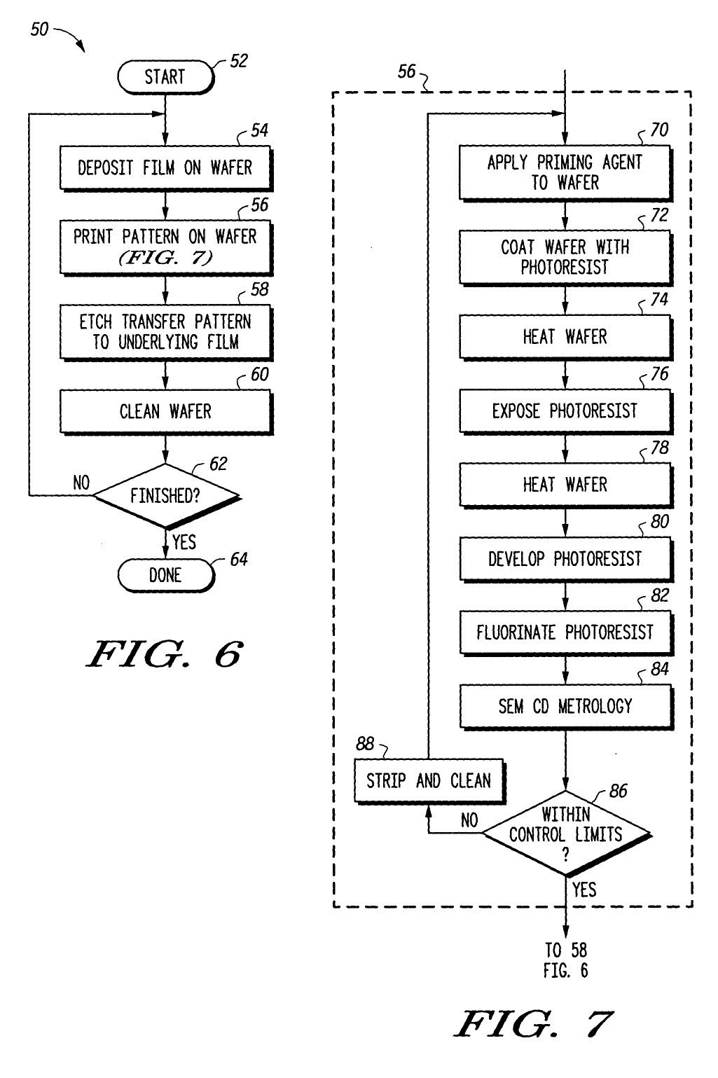

FIG. 6 is a flow diagram of a method 50 for patterning a semiconductor device with substantial elimination of resist linewidth slimming according to one embodiment of the present disclosure. The method begins with the start of the semiconductor manufacturing process designated by reference numeral 52, including providing a wafer. Various layers are deposited upon the wafer, wherein the particular types of layers and patterns in said layers depends upon the type of semiconductor device or devices being fabricated, using techniques known in the art. In step 54, a film, such as a polysilicon layer, is deposited onto the wafer.

In step 56, the method includes printing a pattern onto the film on the wafer, as will be further explained herein with respect to FIG. 7. Subsequent to printing the pattern on the wafer, the pattern is etch transferred to the underlying film using techniques known in the art for etching of the particular underlying film, as indicated by reference numeral 58. At step 60, the method includes cleaning the wafer. At step 62, a query is made to determine whether the entire chip manufacturing process is finished. If not finished, then method 50 returns to step 54, with the deposition of another film on the wafer. If finished, then processing terminates at 64.

FIG. 7 is a flow diagram of the wafer patterning process of step 56 in the flow diagram of FIG. 6, presented in greater detail according to one embodiment of the present disclosure. Printing a pattern on the wafer begins with applying a priming agent to the wafer at step 70. The priming agent operates to improve an adhesion between a photoresist and an underlying layer that the photoresist is to be deposited on. In step 72, the method includes coating the wafer with a photoresist. In step 74, the wafer is heated for a duration of time sufficient to drive off any solvents remaining in the particular photoresist applied in step 72. Next, in step 76, the photoresist is exposed through a reticle or mask, using illumination from a source of illumination appropriate for the photoresist exposure.

Subsequent to exposing the photoresist in step 76, the wafer is heated again in step 78, as may be required for the particular photoresist being used. For example, the particular photoresist may require additional heating of the wafer after photoresist exposure to drive desired photochemical changes to completion, wherein the photochemical changes correspond to changes initiated during the exposure step. Next, the method includes developing the photoresist at step 80 according to the requirements for developing the respective photoresist. Subsequent to developing the photoresist, the method includes subjecting the developed photoresist to a fluorination step (step 82) according to the embodiments of the present disclosure.

The fluorination step can include one of a gas phase F₂/inert gas, atomic F from a plasma, and liquid phase. In one embodiment, exposing the photoresist layer to fluorine includes exposing the photoresist layer to a gas comprising fluorine. The gas can include molecular fluorine (F₂) in an inert carrier gas, the inert carrier gas comprising one or more of nitrogen (N₂), helium (He), and argon (Ar). In an alternate embodiment, the gas is dissociated into atomic fluorine from a gas containing fluorine, for example, one or more of the following: nitrogen trifluoride (NF₃), sulfur hexafluoride (SF₆), xenon difluoride (XeF₂), and molecular fluorine (F₂) via a plasma.

In another embodiment, exposing the photoresist layer to fluorine can also include exposing the photoresist layer to a liquid comprising fluorine. The liquid can include one or more of 1-fluoro-4-hydroxy-1,4-diazoniabicyclo[2.2.2]octane bis(tetrafluoroborate), N-fluoropyridinium pyridine heptafluorodiborate, and N-fluorobenzenesulfonimide.

Subsequent to the fluorination of the developed photoresist, the method includes subjecting the wafer to SEM critical dimension metrology (step 84). During SEM critical dimension metrology, the wafer is bombarded with electrons in a region of interest, for determining the critical dimension of a desired feature of the developed photoresist pattern. Fluorination of the developed photoresist pattern according to the embodiments of the present disclosure substantially eliminates any undesirable resist linewidth slimming.

Responsive to the results of the SEM CD metrology, step 86 queries whether the critical dimensions of the patterned photoresist feature determined from the SEM CD metrology step are within desired control limits of the patterned photoresist feature or features. Responsive to the SEM determined critical dimensions falling outside of the control limits, the method proceeds to a strip and clean step, as indicated by reference numeral 88. Strip and clean includes removing the patterned photoresist from the wafer and cleaning the wafer surface in preparation for repeating the process beginning again with step 70. On the other hand, responsive to the SEM determined critical dimensions falling within the desired control limits, the process then proceeds to step 58 in FIG. 6, and continues as discussed herein above.

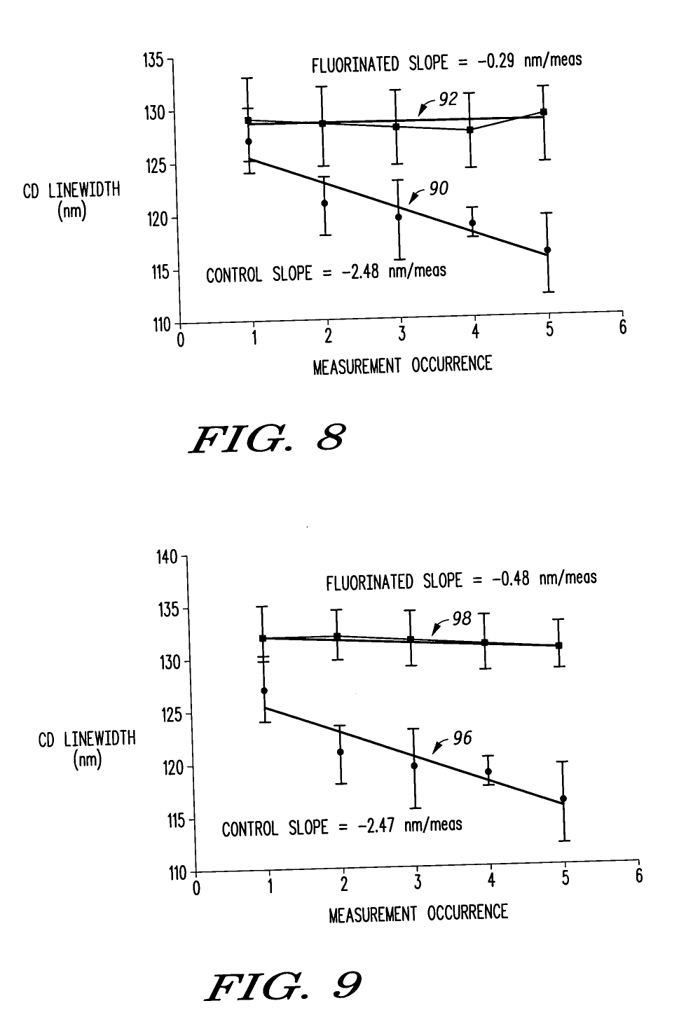

FIG. 8 is a graphical representation illustrating changes in critical dimension linewidth versus a number of occurrences an SEM measurement is taken on untreated pattern lines of a dense line pattern and treated pattern lines of the same dense line pattern. A dense line pattern is one in which the space between adjacent lines of the pattern is on the same order of magnitude as the width of respective lines. The critical dimension linewidth of the untreated lines is illustrated by circles and a solid line is drawn through a best fit of the circles, as indicated by reference numeral 90. The critical dimension linewidth of lines treated according to the embodiments of the present disclosure are illustrated by squares and a solid line is drawn through a best fit of the squares, as indicated by reference numeral 92.

As can be observed from the graph, line 90 has a slope indicative of a decrease in linewidth on the order of approximately 2.5 nm per occurrence of an SEM measurement on the untreated lines of the dense line pattern. In comparison, line 92 has a slope indicative of a decrease in linewidth on the order of approximately 0.3 nm per occurrence of an SEM measurement on the treated lines of the dense line pattern. Accordingly, an approximate order of magnitude improvement in the reduction of linewidth slimming is obtained with the use of the embodiments of the present disclosure.

FIG. 9 is a graphical representation illustrating changes in critical dimension linewidth versus a number of occurrences an SEM measurement is taken on untreated pattern lines of a semi-dense line pattern and treated pattern lines of the same semi-dense line pattern. A semi-dense line pattern is one in which the space between adjacent lines of the pattern is on the order of two or more times the width of respective lines. The critical dimension linewidth of the untreated lines is illustrated by circles and a solid line is drawn through a best fit of the circles, as indicated by reference numeral 96. The critical dimension linewidth of lines treated according to the embodiments of the present disclosure are illustrated by squares and a solid line is drawn through a best fit of the squares, as indicated by reference numeral 98.

As can be observed from the graph, line 96 has a slope indicative of a decrease in linewidth on the order of approximately 2.5 nm per occurrence of an SEM measurement on the untreated lines of the dense line pattern. In comparison, line 98 has a slope indicative of a decrease in linewidth on the order of approximately 0.5 nm per occurrence of an SEM measurement on the treated lines of the dense line pattern. Accordingly, an improvement in the reduction of linewidth slimming on the order of approximately 5 (five) times is obtained with the use of the embodiments of the present disclosure.

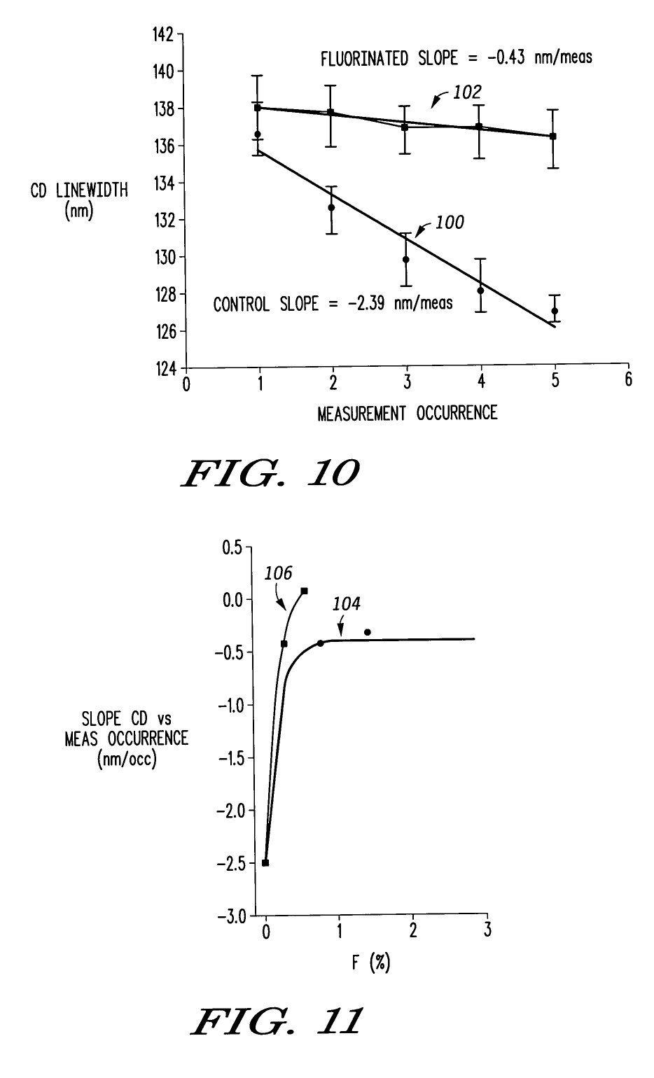

FIG. 10 is a graphical representation illustrating changes in critical dimension linewidth versus a number of occurrences an SEM measurement is taken on untreated pattern lines of an isolated line pattern and treated pattern lines of the same isolated line pattern. An isolated line pattern is one in which the space between adjacent lines of the pattern is on the order of ten or more times the width of respective lines. The critical dimension linewidth of the untreated lines is illustrated by circles and a solid line is drawn through a best fit of the circles, as indicated by reference numeral 100. The critical dimension linewidth of lines treated according to the embodiments of the present disclosure are illustrated by squares and a solid line is drawn through a best fit of the squares, as indicated by reference numeral 102.

As can be observed from the graph, line 100 has a slope indicative of a decrease in linewidth on the order of approximately 2.4 nm per occurrence of an SEM measurement on the untreated lines of the dense line pattern. In comparison, line 102 has a slope indicative of a decrease in linewidth on the order of approximately 0.4 nm per occurrence of an SEM measurement on the treated lines of the dense line pattern. Accordingly, an improvement in the reduction of linewidth slimming on the order of approximately 5 (five) times is obtained with the use of the embodiments of the present disclosure.

FIG. 11 is a graphical representation of suppression of resist slimming by fluorination as a function of percentage fluorine according to one embodiment of the present disclosure. The change in linewidth per measurement occurrence as a function of fluorine concentration according to an embodiment of the present disclosure that includes usage of atomic fluorine is illustrated by circles and a solid line is drawn through a best fit of the circles, as indicated by reference numeral 104. The change in linewidth per measurement time as a function of fluorine concentration according to an embodiment of the present disclosure that includes usage of molecular fluorine are illustrated by squares and a solid line is drawn through a best fit of the squares, as indicated by reference numeral 106. As can be viewed from FIG. 11, an undesired resist slimming effect is substantially eliminated at a fluorine concentration on the order of between 0.5% to 0.75%, depending upon the fluorination conditions.

The ultimate desired change in linewidth per measurement time is zero, i.e. no change in linewidth per measurement occurrence. With respect to the usage of atomic fluorine, as illustrated by reference numeral 104, an improved change in linewidth per measurement occurrence is achieved at a fluorine concentration of approximately 0.8% (eight tenths of one percent). With respect to the usage of molecular fluorine, as illustrated by reference numeral 106, an improved change in linewidth per measurement occurrence is achieved at a fluorine concentration of approximately 0.5% (one half percent).

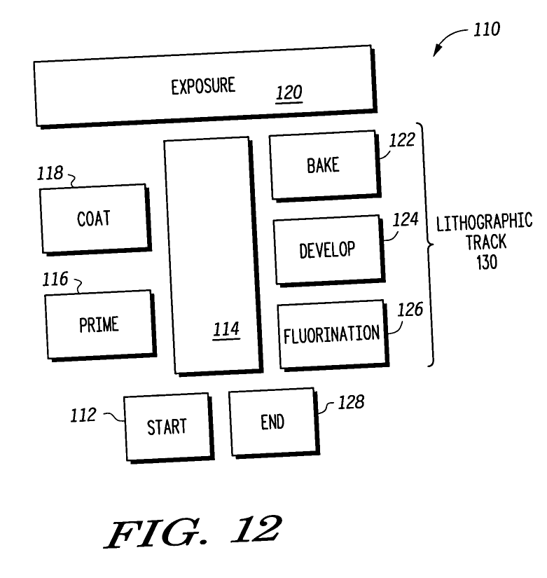

FIG. 12 illustrates a block diagram view of a system for use in a portion of a process for making a semiconductor device according to one embodiment of the present disclosure. Wafers are loaded into the system 110 at start module 112 and transferred to various other modules via wafer handling and transfer system 114. The various other modules include a prime module 116, coat module 118, exposure unit 120, bake module 122, develop module 124 and fluorination module 126. Fluorination module 126 is configured to carry out the various fluorination techniques according to the embodiments of the present disclosure, as discussed herein. Subsequent to processing of the wafer by the system 110, the wafer is unloaded at end module 128. Modules 112-118 and modules 122-128 make up a lithography track 130.

Accordingly, an apparatus is described for making a semiconductor device, wherein the semiconductor device includes a substrate, an insulating layer formed on the substrate, a conductive layer formed on the insulating layer, and a photoresist layer formed on the conductive layer. The apparatus includes a fluorination module. The fluorination module is configured for exposing the photoresist layer of the semiconductor device to fluorine. The fluorination module is further configured for exposing the photoresist layer to fluorine after the photoresist layer is patterned. In one embodiment, the fluorination module is for exposing the photoresist layer to a gas comprising fluorine. In another embodiment, the fluorination module is for exposing the photoresist layer to a liquid comprising fluorine.

According to another embodiment, a semiconductor device includes a substrate; an insulating layer formed over the substrate; a conductive layer formed over the insulating layer; and a photoresist layer formed over the conductive layer, the photoresist layer being exposed to fluorine after being formed on the conductive layer. The photoresist layer is a patterned photoresist layer. The conductive layer is formed using one or more of a group consisting of metal, silicon, and germanium.

In one embodiment, the fluorine is in a gaseous form, wherein the fluorine is dissociated from one of nitrogen trifluoride (NF₃), sulfur hexafluoride (SF₆), xenon difluoride (XeF₂), and molecular fluorine (F₂). The semiconductor device may also be formed wherein the fluorine is dissociated via a plasma. Such a plasma can be incorporated into the lithography track discussed above, or it can be done in a separate chamber in an etch reactor. Still further, the semiconductor device may also be formed in that the fluorine is in a liquid form, wherein the liquid comprises one or more of 1-fluoro-4-hydroxy-1,4-diazoniabicyclo[2.2.2]octane bis(tetrafluoroborate), N-fluoropyridinium pyridine heptafluorodiborate, and N-fluorobenzenesulfonimide.

In the foregoing specification, the disclosure has been described with reference to various embodiments. However, one of ordinary skill in the art appreciates that various modifications and changes can be made without departing from the scope of the present embodiments as set forth in the claims below. Accordingly, the specification and figures are to be regarded in an illustrative rather than a restrictive sense, and all such modifications are intended to be included within the scope of the present embodiments.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the term “comprises,” “comprising,” or any other variation thereof, are intended to cover a non-exclusive inclusion, such that a process, method, article, or apparatus that comprises a list of elements does not include only those elements by may include other elements not expressly listed or inherent to such process, method, article, or apparatus.

1. A method for forming a semiconductor device comprising:
providing a substrate;
forming a predetermined layer on the substrate;
forming a photoresist layer on the predetermined layer; and
exposing the photoresist layer to fluorine to produce a fluorinated photoresist layer.

2. The method of claim 1, wherein the photoresist layer is a patterned photoresist layer.

3. The method of claim 2, further comprising using a scanning electron microscope (SEM) to measure a dimension of a portion of the patterned photoresist layer, wherein the dimension is substantially unchanged by an electron beam emitted by the SEM.

4. The method of claim 3, further comprising etching the portion of the patterned photoresist layer to change the dimension to a smaller dimension.

5. The method of claim 3, wherein the portion of the patterned photoresist layer is for forming a control electrode of a transistor.

6. The method of claim 1, wherein the exposing the photoresist layer to fluorine further comprises exposing the photoresist layer to a gas comprising fluorine.

7. The method of claim 6, wherein the gas is molecular fluorine (F₂) in an inert carrier gas, the inert carrier gas comprising one or more of nitrogen (N₂), helium (He), and argon (Ar).

8. The method of claim 6, wherein a source of the fluorine comprises one or more of nitrogen trifluoride (NF₃), sulfur hexafluoride (SF₆), xenon difluoride (XeF₂), and molecular fluorine (F₂).

9. The method of claim 6, wherein the gas is dissociated into atomic fluorine from one of nitrogen trifluoride (NF₃), sulfur hexafluoride (SF₆), xenon difluoride (XeF₂), and molecular fluorine (F₂) via a plasma.

10. The method of claim 1, wherein the exposing the photoresist layer to fluorine further comprises exposing the photoresist layer to a liquid comprising fluorine.

11. The method of claim 10, wherein the liquid comprises one or more of 1-fluoro-4-hydroxy-1,4-diazoniabicyclo[2.2.2]octane bis(tetrafluoroborate), N-fluoropyridinium pyridine heptafluorodiborate, and N-fluorobenzenesulfonimide.

12. The method of claim 1, wherein the predetermined layer comprises one of a conductive material, a semiconductive material or an insulating material.

13. A semiconductor device comprising:
a substrate;
an insulating layer formed over the substrate;
a conductive layer formed over the insulating layer; and
a photoresist layer formed over the conductive layer, the photoresist layer being exposed to fluorine after being formed on the conductive layer.

14. The semiconductor device of claim 13, wherein the photoresist layer is a patterned photoresist layer.

15. The semiconductor device of claim 13, wherein the conductive layer is formed using one or more of a group consisting of metal, silicon, and germanium.

16. The semiconductor device of claim 1, wherein the fluorine is in a gaseous form.

17. The semiconductor device of claim 16, wherein the fluorine is dissociated from one of nitrogen trifluoride (NF₃), sulfur hexafluoride (SF₆), xenon difluoride (XeF₂), and molecular fluorine (F₂).

18. The semiconductor device of claim 17, wherein the fluorine is dissociated via a plasma.

19. The semiconductor device of claim 16, wherein fluorine is in a liquid form.

20. The semiconductor device of claim 19, wherein the liquid comprises one or more of 1-fluoro-4-hydroxy-1,4-diazoniabicyclo[2.2.2]octane bis(tetrafluoroborate), N-fluoropyridinium pyridine heptafluorodiborate, and N-fluorobenzenesulfonimide.

21. An apparatus for making a semiconductor device, the semiconductor device including a substrate, an insulating layer formed on the substrate, a conductive layer formed on the insulating layer, and a photoresist layer formed on the conductive layer, the apparatus comprising a fluorination module, the fluorination module for exposing the photoresist layer of the semiconductor device to fluorine.

22. The apparatus of claim 21, wherein the fluorination module is for exposing the photoresist layer to fluorine after the photoresist layer is patterned.

23. The apparatus of claim 21, wherein the fluorination module is for exposing the photoresist layer to a gas comprising fluorine.

24. The apparatus of claim 21, wherein the fluorination module is for exposing the photoresist layer to a liquid comprising fluorine.
